(19) United States
(12) Patent Application Publication
(10) Pub. No.: US 2018/0212169 A1
(43) Pub. Date: Jul. 26, 2018

(54) DISPLAY DEVICE AND METHOD FOR MANUFACTURING THE SAME

(71) Applicant: Japan Display Inc., Tokyo (JP)

(72) Inventor: Yusuke GOTO, Tokyo (JP)

(21) Appl. No.: 15/867,248

(22) Filed: Jan. 10, 2018

(30) Foreign Application Priority Data
Jan. 25, 2017 (JP) 2017-011337

(51) Int. Cl. H01L 51/00; H01L 51/56; H01L 51/52

(52) U.S. Cl. CPC H01L 51/0097; H01L 2251/5338; H01L 51/5253; H01L 51/56

(57) ABSTRACT

A method for manufacturing a display device includes forming a display portion and a peripheral portion including a terminal portion on a first surface of a substrate, the peripheral portion being away from the display portion; bonding a protecting member and a second surface of the substrate with an adhesive member; making adhesive strengths of a first region and a second region of the adhesive member different from each other; and removing a portion of the protective member from the substrate, the portion facing the first region. The first region of the adhesive member includes a portion facing an intermediate portion which is between the display portion and the peripheral portion, and the second region of the adhesive member includes a portion adjacent to the first region and facing the display portion or the peripheral portion.

### CROSS REFERENCE TO RELATED APPLICATIONS

This application is based upon and claims the benefit of priority from the prior Japanese Patent Application No. 2017-011337, filed on Jan. 25, 2017, the entire contents of which are incorporated herein by reference.

### FIELD

An embodiment according to the present invention relates to a display device including a foldable flexible substrate and a method for manufacturing the same.

### BACKGROUND

As display devices which are usable for electronic devices, a liquid crystal display device using an electro-optical effect of a liquid crystal material and an organic EL (electroluminescence) display device including an organic electroluminescence (EL) element have been developed and put into actual products.

Especially, an organic EL element, when being used as a display element, has a feature of realizing a wide viewing angle and high definition display, and also of being allowed to be located on a flexible substrate. Japanese Laid-Open Patent Publication No. 2011-209405 discloses a display device including a flexible substrate that is foldable at a wiring portion connecting a pixel array portion and a peripheral circuit portion to each other. Such a structure allows a bezel of the display device to be narrower, which decreases the size of the display device.

### SUMMARY

An embodiment of the present invention provides a method for manufacturing a display device. The method includes forming a display portion and a peripheral portion including a terminal portion on a first surface of a substrate, the peripheral portion being away from the display portion; bonding a protecting member and a second surface of the substrate with an adhesive member (or viscous member), the second surface facing the first surface; making an adhesive strength (or viscous strength) of a first region of the adhesive member (or viscous member) and an adhesive strength (or viscous strength) of a second region of the adhesive member (or viscous member) different from each other; and removing a portion of the protective member from the substrate, the portion facing the first region. The first region of the adhesive member (or viscous member) includes a portion facing an intermediate portion which is between the display portion and the peripheral portion, and the second region of the adhesive member (or viscous member) includes a portion adjacent to the first region and facing the display portion or the peripheral portion.

Another embodiment of the present invention provides a display device including a substrate having a first surface and a second surface facing the first surface; a display portion located on the first surface, the display portion including pixels; a peripheral portion located on the first surface and being away from the display portion, the peripheral portion including a terminal portion; a first protective member located on the second surface, the first protective member facing the display portion; a second protective member located on the second surface, the second protective member facing the peripheral portion; a first adhesive member located between the second surface and the first protective member; a second adhesive member located between the second surface and the second protective member; and a third adhesive member located at a first portion adjacent to a first end of the first adhesive member and at a second portion adjacent to a second end of the second adhesive member, the first end facing the second adhesive member, the second end facing the first adhesive member, the second portion separated from the first portion. The third adhesive member has an adhesive strength weaker than an adhesive strength of the first adhesive member and an adhesive strength of the second adhesive member.

### BRIEF EXPLANATION OF THE DRAWINGS

FIG. 1 is a plan view of a display device in an embodiment according to the present invention;

FIG. 2 is a cross-sectional view of the display device in an embodiment according to the present invention;

FIG. 3 is an exploded perspective view showing a method for manufacturing the display device in an embodiment according to the present invention;

FIG. 4 is a cross-sectional view showing the method for manufacturing the display device in an embodiment according to the present invention;

FIG. 5 is a cross-sectional view showing the method for manufacturing the display device in an embodiment according to the present invention;

FIG. 6 is a cross-sectional view showing the method for manufacturing the display device in an embodiment according to the present invention;

FIG. 7 is a cross-sectional view showing the method for manufacturing the display device in an embodiment according to the present invention;

FIG. 8 is a cross-sectional view showing the method for manufacturing the display device in an embodiment according to the present invention;

FIG. 9 is a cross-sectional view showing the method for manufacturing the display device in an embodiment according to the present invention;

FIG. 10 is a cross-sectional view showing the method for manufacturing the display device in an embodiment according to the present invention;

FIG. 11 is a plan view showing the method for manufacturing the display device in an embodiment according to the present invention;

FIG. 12 is a cross-sectional view showing the method for manufacturing the display device in an embodiment according to the present invention; and

FIG. 13 is a cross-sectional view showing a method for manufacturing a display device according to a conventional example.

### DESCRIPTION OF EMBODIMENTS

A display device including a flexible substrate may be manufactured as follows. In a protective film that is to be provided on a rear surface of the substrate, a slit-like opening is formed at a position corresponding to a foldable portion of the substrate. Then, the protective film is pasted to the rear surface of the substrate. This improves the foldability of the foldable portion. In addition, since the slit-like opening is formed in the protective film before the protective film is pasted to the rear surface, the entirety of the protective film is pasted to the substrate in one step. This simplifies the manufacturing process and decreases the manufacturing cost. However, the flexible substrate is thinner than a conventional non-flexible substrate, and therefore, is more easily influenced by the manufacturing process. For example, since the slit-like opening is formed in the protective film, the flexible substrate has a film end portion on the foldable portion. The film end portion is subjected to a local load, which may cause concentration of a stress on lines on the flexible substrate and thus may cause breakage of the lines. Such breakage of the lines causes a display fault.

In light of such a problem, embodiments of the present invention have an object of protecting lines of a display device including a flexible substrate.

Hereinafter, embodiments according to the present invention will be described with reference to the drawings. This disclosure merely provides an example, and modifications or alterations thereof readily conceivable by a person of ordinary skill in the art without departing from the gist of the present invention are duly encompassed in the scope of the present invention. In the drawings, components may be shown schematically regarding the width, thickness, shape and the like, instead of being shown in accordance with the actual sizes, for the sake of clearer illustration. The drawings are merely examples and do not limit the interpretations of the present invention in any way.

In the specification and the drawings, components that have substantially the same functions as those described before with reference to a previous drawing(s) bear the identical reference signs thereto, and detailed descriptions thereof may be omitted. The words “first”, “second” and the like provided for components are used merely to distinguish the components from each other, and do not have any further meaning unless otherwise specified.

In the specification and the claims, an expression that a component or a region is “on” another component or region encompasses a case where such a component or region is in direct contact with the other component or region and also a case where such a component is above or below the other component or region, namely, a case where still another component or region is provided between such a component or region and the other component or region, unless otherwise specified. In the following description, unless otherwise specified, the side on which a display element is provided with respect to a substrate as seen in a cross-sectional view will be referred to as “above”, and the opposite side will be referred to as “below”.

In this specification, the expressions that “α includes A, B or C”, “α includes any of A, B and C”, and “a includes one selected from the group consisting of A, B and C” do not exclude a case where a includes a plurality of combinations of A to C unless otherwise specified. The above expressions do not exclude a case where α include an element other than A, B and C.

### <1. Structure of the Display Device>

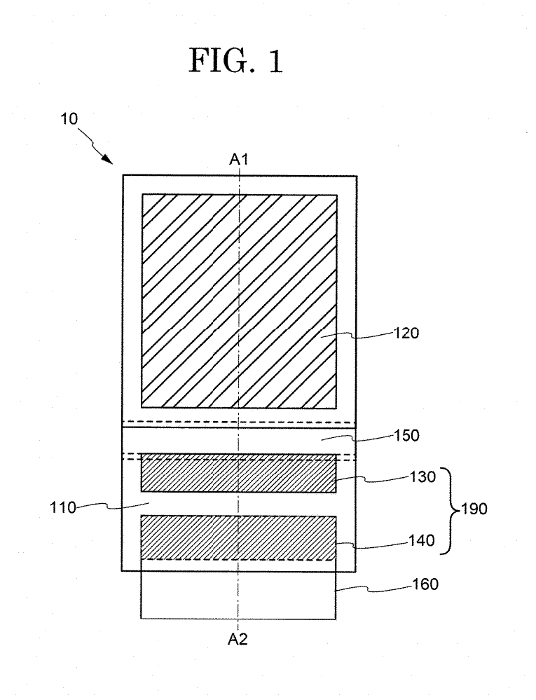

FIG. 1 is a plan view of a display device 10 in an embodiment according to the present invention. As shown in FIG. 1, the display device 10 includes a substrate 110, a display portion 120, a driving circuit 130, a terminal portion 140 including terminals connectable with lines connected with the display portion 120 and the driving circuit 130, and a flexible printed circuit 160.

The substrate 110 is formed of an organic resin material as a foldable material. For example, the substrate 110 is formed of an organic resin material such as a polyimide resin, an acrylic resin, an epoxy resin, polyethylene terephthalate or the like. The substrate 110 has a thickness that is appropriately set in the range of 10 μm to several hundred micrometers.

The display portion 120 includes pixels provided in an array. In the case where the display device 10 is of an active matrix type, each of the pixels includes a thin film transistor and a display element. The thin film transistor drives the display element based on an external signal input via the flexible printed circuit 160 or a signal from the driving circuit 130 to display a still image or a moving image. The display element is, for example, an organic EL element. The display portion 120, the driving circuit 130 and the flexible printed circuit 160 are connected with each other via a line provided on the substrate 110.

The driving circuit 130 includes at least one of a driving circuit driving a scanning line (source driver) and a driving circuit driving a signal line (gate driver), and outputs a signal to the thin film transistor in the display portion 120. The driving circuit 130 is formed of an integrated circuit such as an ASIC (Application Specific Integrated Circuit) or the like.

The flexible printed circuit 160 may receive a signal from an external circuit and transmit the signal to the driving circuit 130. The flexible printed circuit 160 includes a flexible resin substrate and a plurality of lines provided thereon, and is electrically connected with the terminal portion 140 provided on the substrate 110. The driving circuit 130 may be located on the flexible printed circuit 160.

A region that is outer to the display portion 120 and has the driving circuit 130 and the terminal portion 140 located thereon may be referred to as a “peripheral portion 190”. An intermediate region between the display portion 120 and the peripheral portion 190 is a foldable portion 150. The display device 10 is folded along the foldable portion 150.

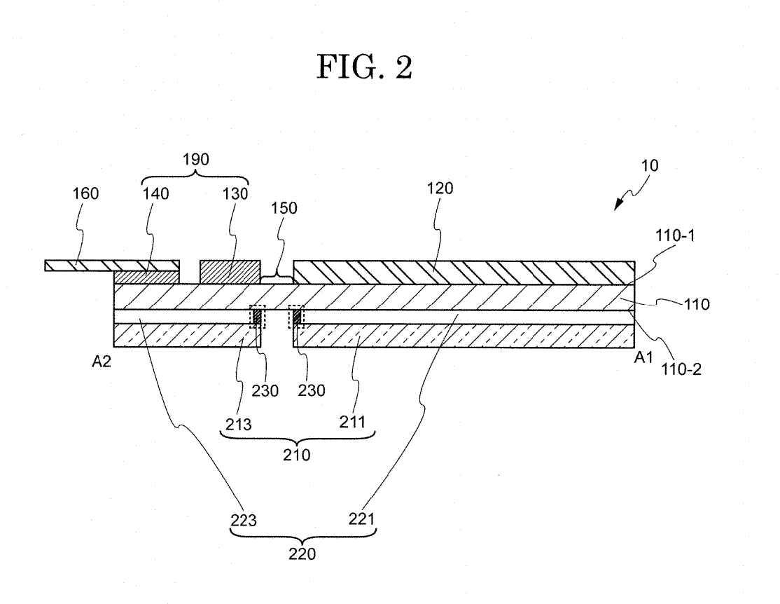

Now, FIG. 2 is a cross-sectional view of the display device 10 taken along line A1-A2 in FIG. 1. As shown in FIG. 2, the display device 10 includes the substrate 110, the display portion 120, the driving circuit 130, the terminal portion 140, the flexible printed circuit 160, and also a protective member 210 and an adhesive member 220. A viscous member may be provided instead of the adhesive member 220. The viscous member contains a highly viscous material or a gel-type solid material. In this embodiment, the descriptions on the adhesive strength are also applicable to a viscous strength. The display element included in the display portion 120 is an organic EL element. As shown in FIG. 2, the substrate 110 has a first surface 110-1 and a second surface 110-2 facing the first surface 110-1. The display portion 120, the driving circuit 130, the terminal portion 140 and the flexible printed circuit 160 are located on the first surface 110-1 of the substrate 110. The protective member 210 and the adhesive member 220 are located on the second surface 110-2.

The protective member 210 has a function of protecting a target. The protective member 210 is formed of an organic resin film. The protective member 210 is, for example, formed of a film containing an organic resin material such as a polyimide resin, an acrylic resin, an epoxy resin, polyethylene terephthalate or a silicone-based organic resin. Alternatively, the protective member 210 may be formed of an organic resin film containing any of the above-described organic resin materials and an inorganic material. Still alternatively, the protective member 210 may be formed of a metal material such as stainless steel, copper or the like. The protective member 210 may have a thickness that is sufficient to protect the display device 10. For example, the protective member 210 may have a thickness appropriately set in the range of 100 μm to 200 μm. A portion of the protective member 210 that faces the display portion 120 may be labeled as a first protective member 211, and a portion of the protective member 210 that faces the peripheral portion 190 may be labeled as a second protective member 213.

As shown in FIG. 2, the adhesive member 220 includes a first adhesive member 221 and a second adhesive member 223. The first adhesive member 221 is located between the second surface 110-2 of the substrate 110 and the first protective member 211. The first adhesive member 221 has a function of bonding the substrate 110 and the first protective member 211 to each other. The second adhesive member 223 is located between the second surface 110-2 of the substrate 110 and the second protective member 213. The second adhesive member 223 has a function of bonding the substrate 110 and the second protective member 213 to each other. The first adhesive member 221 and the second adhesive member 223 are formed of an organic resin material. The organic resin material may be a material reactive to heat such as a thermoplastic material, thermosetting material or the like. Alternatively, the organic resin material may be a material reactive to light, such as a photo-softening material, a photocurable material or the like. For example, the first adhesive member 221 and the second adhesive member 223 are formed of a polyimide resin, an acrylic resin, an epoxy resin, polymethacrylate, melamine, vinyl chloride, or a silicon-based resin.

On the second surface 110-2 of the substrate 110, an adhesive member 230 (third adhesive member) is located adjacent to the first adhesive member 221 or the second adhesive member 223, along an end of the foldable portion 150. The adhesive member 230 is formed of substantially the same material as that of the first adhesive member 221 and the second adhesive member 223, but has an adhesive strength weaker than that of each of the first adhesive member 221 and the second adhesive member 223.

### <2. Method for Manufacturing the Display Device>

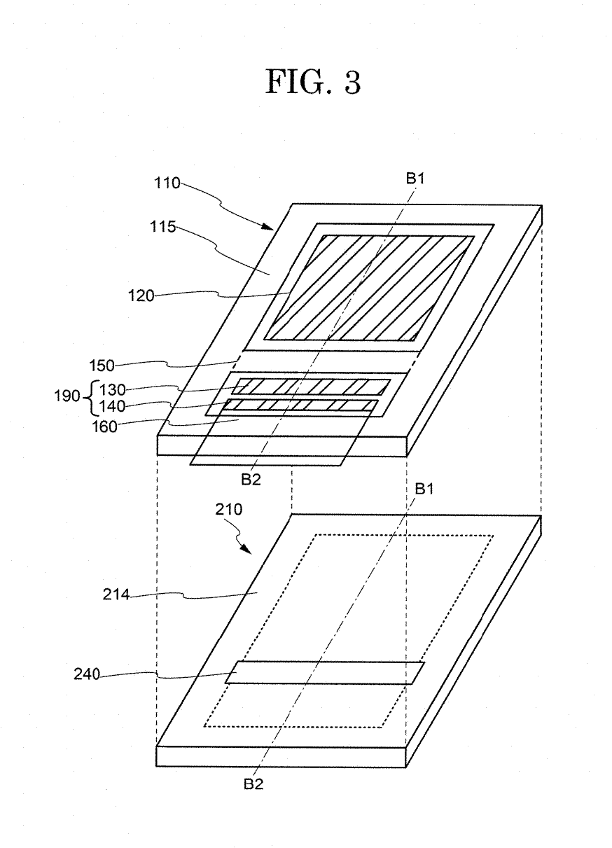

With reference to FIG. 3 to FIG. 11, a method for manufacturing the display device 10 will be described.

### (2-1. Preparation of the Substrate and the Protective Member)

FIG. 3 is an exploded perspective view showing the substrate 110 and the protective member 21 before the substrate 110 and the protective member 21 are bonded together. As shown in FIG. 3, the substrate 110 has the display portion 120, the peripheral portion 190 including the driving circuit 130 and the terminal portion 140, and the flexible printed circuit 160 provided thereon in advance. The substrate 110 is formed of a polyimide resin as a foldable material. Before the step of forming the display portion 120, the peripheral portion 190 including the driving circuit 130 and the terminal portion 140, and the flexible printed circuit 160 on the substrate 110, a rigid support substrate (e.g., glass substrate) may be provided on the second surface 110-2 of the substrate 110. After the display portion 120, the peripheral portion 190 and the flexible printed circuit 160 are formed on the substrate 110, the support substrate is removed. The display portion 120 may include organic EL elements as the display elements.

The protective member 210 may be formed of an organic resin or of an organic resin containing an inorganic material. The protective member 210 is formed of, for example, an acrylic resin. A portion of the protective member 210 that is to be bonded with the foldable portion 150 of the substrate 110 may have a cut-out portion 240 provided thereon. The cut-out portion 240 does not need to be provided in the entirety of a thickness direction of the protective member 210. For example, the cut-out portion 240 may be formed to a middle of the thickness direction of the protective member 210. More specifically, where the protective member 210 has a first surface facing the substrate 110 and a second substrate opposite thereto, the cut-out portion 240 may be provided to extend from the second surface toward the first surface but not to reach the first surface. This state may be expressed as that “the cut-out portion 240 is half-cut”.

The substrate may include a region 115 to the left and to the right of the display portion 120 and the peripheral portion 190. Similarly, the protective member 210 may include a region 214 in a left portion and a right portion thereof. The region 115 and the region 214 are cut off from the display device 10 in a later step. The provision of the region 115 and the region 214 allows the form of the substrate 110 to be kept easily after the protective member 210 is removed from the foldable portion 150 during the manufacturing of the display device 10.

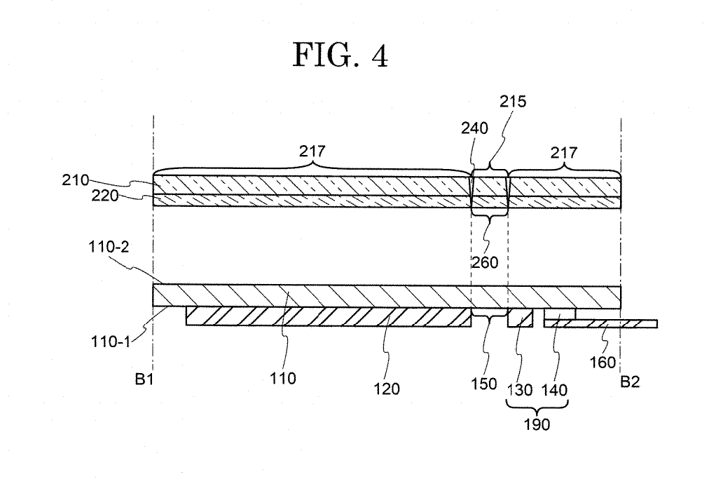

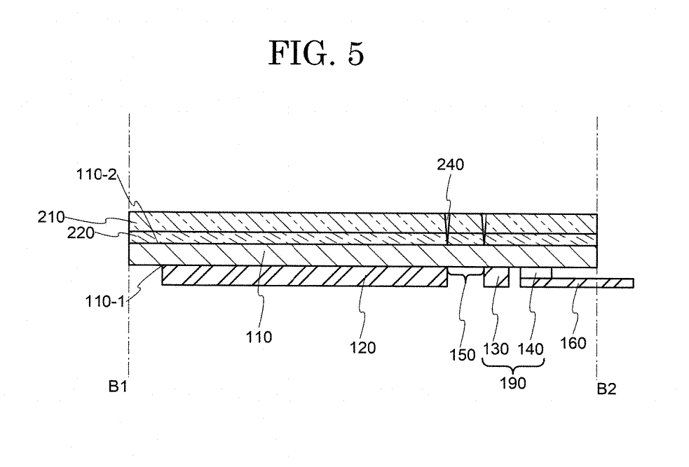

FIG. 4 is a cross-sectional view of the substrate 110 and the protective member 210 taken along line B1-B2 in FIG. 3. As shown in FIG. 4, the display portion 120, the peripheral portion 190 including the driving circuit 130 and the terminal portion 140, and the flexible printed circuit 160 are provided on the first surface 110-1 of the substrate 110. As shown in FIG. 5, the second surface 110-2 of the substrate 110 and the protective member 210 are bonded together with the adhesive member 220. A portion of the protective member 210 that overlaps the foldable portion 150 is a region 215 (third region) shown in FIG. 4, and a portion of the protective member 210 that is adjacent to the region 215 is a region 217 (fourth region) shown in FIG. 4. The cut-out portion 240 is provided between the region 215 and the region 217. Therefore, the region 215 and the region 217 may be away from each other. A portion of the adhesive member 220 that overlaps the foldable portion 150 is a region 260 shown in FIG. 4. The region 260 and the region 215 overlap each other. The adhesive member 220 may be provided on the protective member 210 before the protective member 210 and the substrate 110 are bonded together, and in this case, the adhesive member 220 also has the cut-out portion 240 provided therein. Namely, the cut-out portion 240 may be located as bridging over the protective member 210 and the adhesive member 220. In this case, the cut-out portion 240 is provided along an end of the region 260 of the adhesive member 220.

### (2-2. Bonding of the Protective Member)

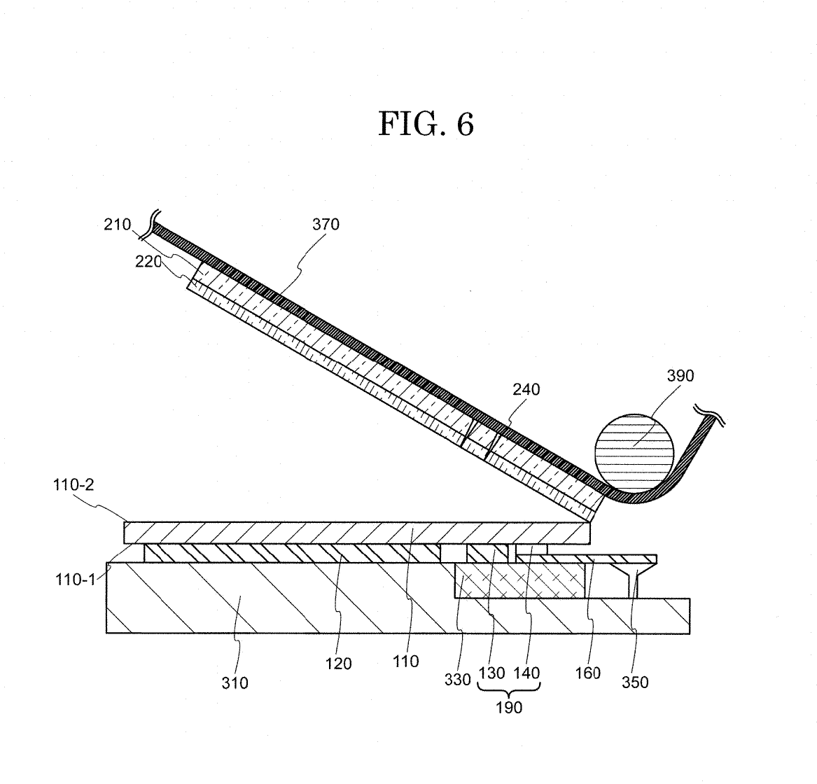

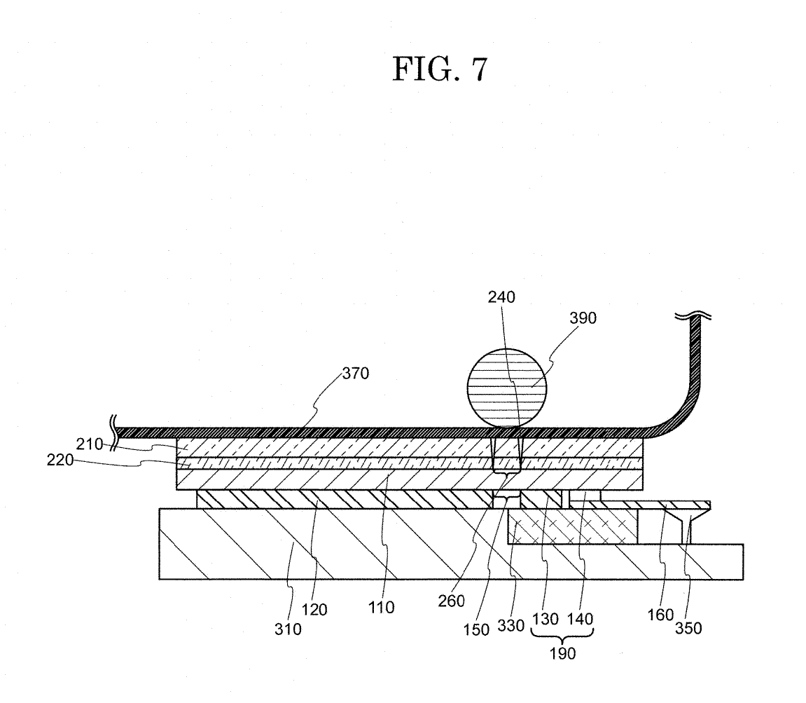

The above-described bonding may be performed as, for example, shown in FIG. 6 and FIG. 7. First, as shown in FIG. 6, the substrate 110 is secured with the second surface 110-2 being directed upward. For example, the display portion 120 is secured to a stage 310. The driving circuit 130 is secured to a cushion stage 330. The terminal portion 140 and the flexible printed circuit 160 are secured to the cushion stage 330 and a stage 350. The protective member 210 is secured to a transportation belt 370. These components may be vacuum-adsorbed or electrostatically adsorbed to be secured. The protective member 210 is in contact with the second surface 110-2 at an end thereof. Next, as shown in FIG. 7, a roller 390 moves to progressively bond the second surface 110-2 of the substrate 110 and the protective member 210 to each other.

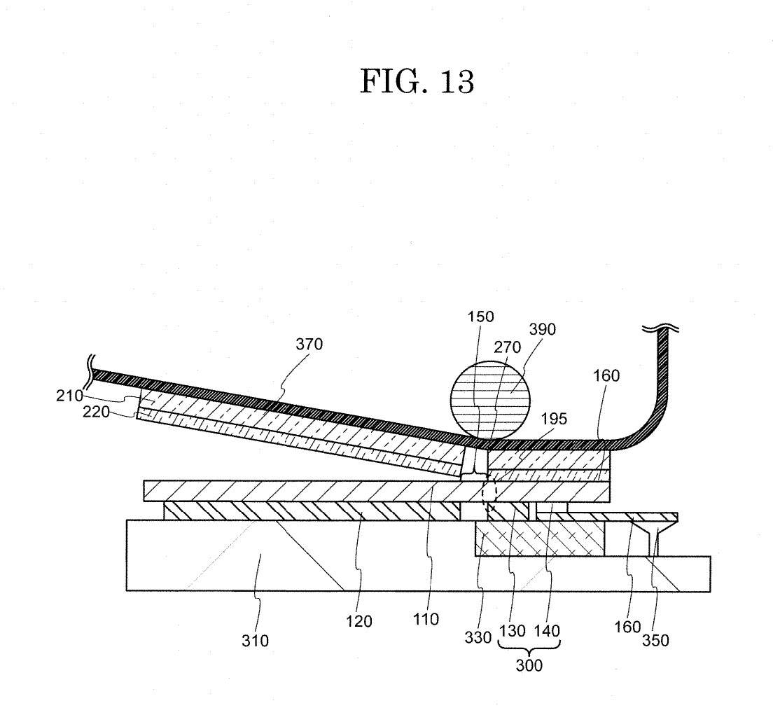

Now, a conventional method referred to as a “lamination method” will be described. Referring to FIG. 13, by the lamination method, a portion of the protective member 210 corresponding to the foldable portion 150 (such a portion corresponds to the region 215 shown in FIG. 4) is removed in advance. Therefore, an end of a surface of the protective member 210 and a surface of the adhesive member 220, in other words, a corner of the protective member 210 and the adhesive member 220 that is located along an end of the removed portion, is formed along an end of the foldable portion 150. In this case, a stepped portion is formed over the corner on the surface of the protective member 210 and the surface of the adhesive member 220. In the step of bonding the second surface 110-2 of the substrate 110 and the protective member 210 to each other, this stepped portion causes a stress to be concentrated on a region 195 shown in FIG. 13, namely, a portion overlapping the corner of the protective member 210 and the adhesive member 220, and in the vicinity of the overlapping portion. Such stress concentration may cause cracks in the substrate 110. Such cracks may break the lines provided on the substrate 110.

By contrast, in this embodiment, as shown in FIG. 7, the surface of the protective member 210 and the surface of the adhesive member 220 that face the second surface 110-2 of the substrate 110 are flat with no stepped portion shown in FIG. 13. Therefore, local concentration of the stress is suppressed in the step of bonding the protective member 210 and the substrate 110 to each other, and thus the substrate 110 is suppressed from being cracked. For this reason, the lines provided on the substrate 110 are prevented from being broken.

### (2-3. Differentiation of Adhesive Strengths)

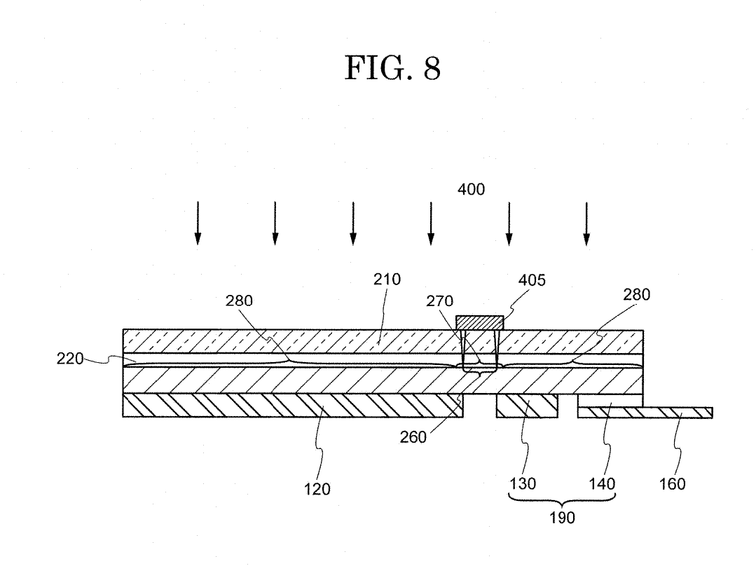

Next, a region 270 (first region) of the adhesive member 220 shown in FIG. 8 is processed to have an adhesive strength different from that of the rest of the adhesive member 220. The region 270 includes the region 260 and extends to the outside of the region 260. More specifically, the region 270 includes the region 260 and also a portion of the adhesive member 220 that corresponds to a part of the display portion 120 that is adjacent to the foldable portion 150 and a portion of the adhesive member 220 that corresponds to a part of the peripheral portion 190 that is adjacent to the foldable portion 150. The adhesive strength of the region 270 is made different from that of the rest of the adhesive member 220 as follows, for example. As shown in FIG. 8, the region 270 is masked by a mask 405 and the assembly of the substrate 110, the protective member 210 and the adhesive member 220 are irradiated with light 400 (e.g., ultraviolet). In this case, the adhesive member 220 is formed of an ultraviolet-curable material. The adhesive member 220 may be formed of an ultraviolet (UV)-curable film. The UV-curable film contains a photopolymerizable resin such as an acrylic resin, an epoxy resin or the like and also contains a photopolymerization initiator, a sensitizer, a filler and the like. For example, the above-described assembly is irradiated with light in an ultraviolet region of 200 nm or longer and 400 nm or shorter, so that the photopolymerization initiator is reacted to cause polymerization of the resin. Then, the polymerization of the resin advances and the resin is cured. As a result of this process, a region 280 (second region) outer to the region 270 of the adhesive member 220 is cured to have the adhesive strength thereof increased. By contrast, the region 270 is not cured, and thus the adhesive strength of the region 270 (first region) and the adhesive strength of the region 280 (second region) are made different from each other.

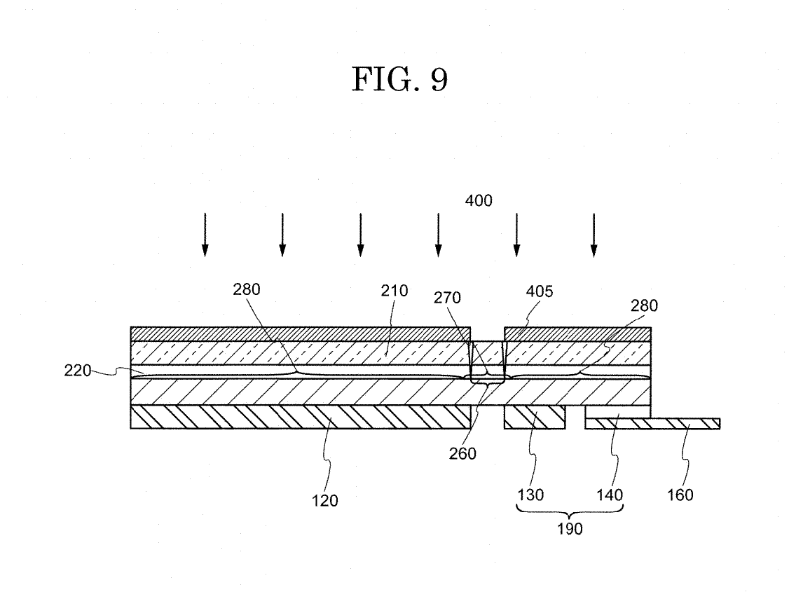

Alternatively, the adhesive strength of the region 270 may be decreased by irradiation of the light 400. In this case, as shown in FIG. 9, the region 280 is masked by the mask 405. The adhesive member 220 is formed of, for example, a UV tape. The UV tape has the adhesive strength thereof decreased when being irradiated with light in the ultraviolet region. As a result of this process, the adhesive strength of the region 270 is decreased, and thus the adhesive strength of the region 270 (first region) and the adhesive strength of the region 280 (second region) are made different from each other.

Still another process for making the adhesive strengths different may be heating. An example of heating may be local heating by use of laser light. In this case, the adhesive member 220 is formed of, for example, a thermoplastic material. Only the region 270 is heated. As a result of this process, the adhesive strength of the region 270 is decreased, namely, is made lower than that of the region 280 adjacent thereto. Thus, the adhesive strength of the region 270 (first region) and the adhesive strength of the region 280 (second region) are made different from each other. Optionally, the adhesive strengths may be made different by a combination of light irradiation and heating performed on the adhesive member 220.

### (2-4. Removal of the Protective Member)

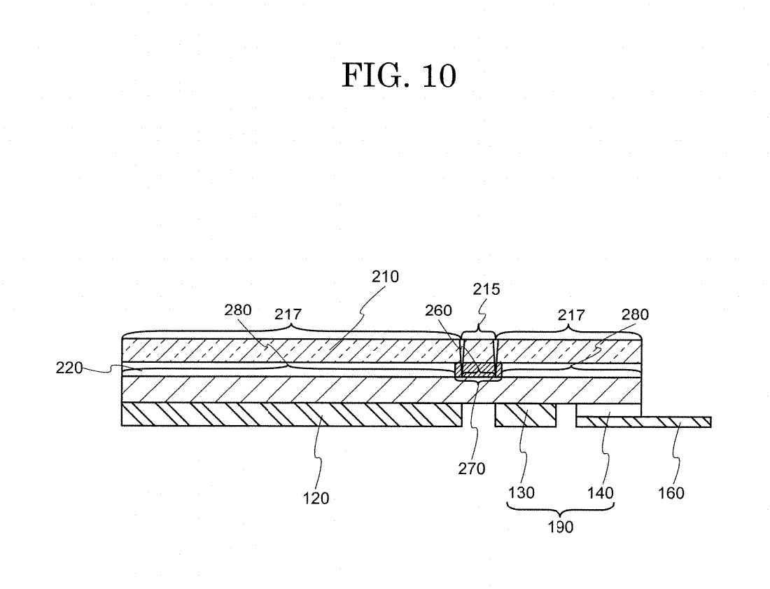

Next, referring to FIG. 10, the region 215 of the protective member 210 and the region 260 of the adhesive member 220 are removed.

In this step, the region 215 of the protective member 210 and the region 260 of the adhesive member 220 may be removed a physical process, a chemical process, heating or light irradiation. As described above, the cut-out portion 240 is provided in the region 215 of the protective member 210 (and the region 260 of the adhesive member 220). In addition, the region 270 of the adhesive member 220, which is larger than the region 260, has the adhesive strength thereof decreased. Namely, a region having a lower adhesive strength is provided in the state where a margin is provided outer to the cut-out portion 240. Therefore, the region 215 of the protective member 210 and the region 260 of the adhesive member 220 are easily removed. After the removal, the region 280 of the adhesive member 220 may be heated or irradiated with light to increase the adhesive strength between the protective member 210 and the substrate 110. The planar size of the region 270 with respect to the region 260 (i.e., margin) may be appropriately set in accordance with the manufacturing method.

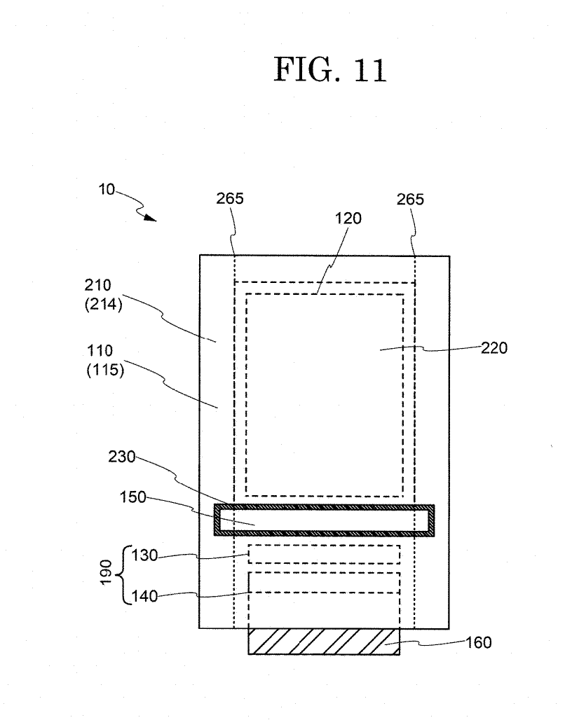

FIG. 11 is a plan view of the second surface 110-2 of the substrate 110 of the display device 10 after the region 215 of the protective member 210 and the region 260 of the adhesive member 220 are removed. As shown in FIG. 11, the adhesive member 230 (third adhesive member) is left in a frame shape. The region 115 of the substrate 110 and the region 214 of the protective member 210, which are respectively provided in order to keep the rigidity of the substrate 110 and the protective member 210, are removed from the display device 10 when such removal is necessary. For example, the region 115 and the region 214 may be cut off along a border 265 shown in FIG. 11. As a result, the protective member 210 is divided into the first protective member 211 (see, for example, FIG. 2) and the second protective member 213. Similarly, the adhesive member 220 is divided into the first adhesive member 221 and the second adhesive member 223 (see, for example, FIG. 2).

By the above-described method, the protective member 210 is located on the rear surface of the substrate 110 with no cracking in the substrate 110 or breakage of the lines in the display device 10. In this case, the protective member 210 is not present on the foldable portion 150. The productivity of the display device 10, which is foldable, is increased.

### <3. Structure of the Display Device in a Folded State>

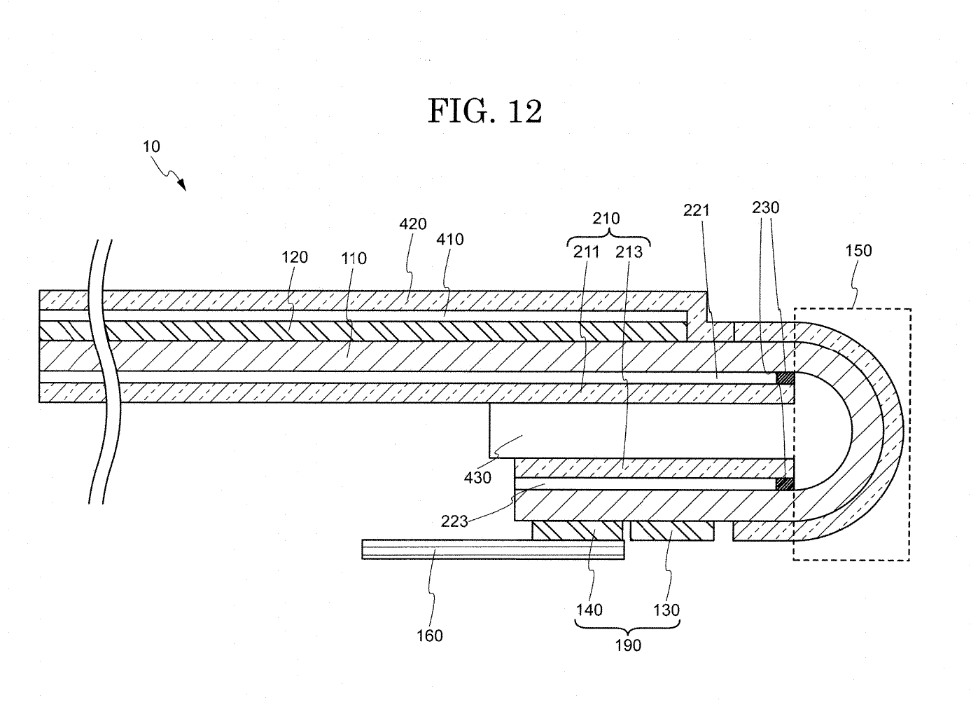

FIG. 12 shows a structure of the display device 10 after the display device 10 is folded.

As shown in FIG. 12, the display device 10 includes the substrate 110, the display portion 120, the driving circuit 130, the terminal portion 140, the flexible printed circuit 160, an adhesive member 410, a protective layer 420, and a spacer 430. The display device 10 is folded along the foldable portion 150.

In the display device 10, the substrate 110 is folded along the foldable portion 150, and the display portion 120 and the peripheral portion 190 overlap each other as seen in a plan view. As shown in FIG. 12, a part of the adhesive member 230 (third adhesive member) as shown in FIG. 11 is located in the display device 10 as being divided into a portion (fourth adhesive member) that is located between the first protective member 211 and the substrate 110 and is adjacent to an end of the first adhesive member 221 and a portion (fifth adhesive member) that is located between the second protective member 213 and the substrate 110 and is adjacent to an end of the second adhesive member 223. The fourth adhesive member and the fifth adhesive member are away from each other.

As shown in FIG. 12, the spacer 430 is located to face the foldable portion 150. A part of the spacer 430 is located between the display portion 120 and the peripheral portion 190. Desirably, the spacer 430 is thicker than the substrate 110 and is formed of a material more rigid than the material of the substrate 110. The spacer 430 is not absolutely necessary. A heat dissipation sheet may be provided between the protective member 210 and the spacer 430. The heat dissipation sheet may be formed of a metal material such as stainless steel, copper or the like.

The protective layer 420 is provided on the display portion 120. The protective layer 420 has a function of protecting the display portion 120. The protective layer 420 may be formed of substantially the same material as that of the protective member 210 or may be formed of a different material from the material used for the protective member 210. The protective layer 420 may be a film-like element or a cured resin, or optionally, a combination of a film-like element and a cured resin. The protective layer 420 provided on the display portion 120 is desirably colorless and transparent. A polarization plate may be optionally provided on the protective layer 420. The protective layer 420 may be formed of a polarization plate (e.g., circularly polarized plate).

The substrate 110 is folded along the foldable portion 150. The above-described method for bonding the protective member 210 and the above-described method for removing the protective member 210 are used, so that the protective member 210 is provided as the first protective member 211 and the second protective member 213, and the first protective member 211 and the second protective member 213 are located away from each other by the size of the foldable portion 150. The protective member 210 (the first protective member 211 and the second protective member 213) is not provided on the foldable portion 150, and therefore, the substrate 110 is easily folded. In the foldable portion 150, the substrate 110 can have a very small radius of curvature of 0.4 mm.

Since the above-described method for bonding the protective member 210 is used, the lines provided on the substrate 110 are not broken or have any other defect, and thus a display fault or the like is suppressed.

In the display device 10 having the above-described structure, as seen in a side view like in FIG. 12, the driving circuit 130 and the flexible printed circuit 160 are provided on the back of the display portion 120. Namely, the structure of the display device 10 in which an end of the substrate 110 is folded decreases the size of the display device 10.

### MODIFICATION

In this embodiment, an organic EL display device is provided as an example. An embodiment of the present invention is also applicable to a liquid crystal display device, any other self-light emitting display device, an electronic paper-type display device including an electrophoretic display element or the like, or any other flat panel display device.

In this embodiment, the cut-out portion 240 is provided in advance in the protective member 210. Alternatively, the cut-out portion 240 may be formed after the adhesive member 230 is formed. In this case, the cut-out portion 240 may be formed by laser light irradiation or by use of a cutting device including a blade. In this embodiment, the substrate 110 and the protective member 210 are bonded to each other with the adhesive member 220. Alternatively, the substrate 110 and the protective member 210 may be bonded to each other with a viscous member.

A person of ordinary skill in the art would readily conceive various alterations or modifications of the present invention, and such alterations and modifications are construed as being encompassed in the scope of the present invention. For example, the display devices in the above-described embodiments may have an element added thereto, or deleted therefrom, or may be changed in design optionally by a person of ordinary skill in the art. The methods in the above-described embodiments may have a step added thereto, or deleted therefrom, or may be changed in the condition optionally by a person of ordinary skill in the art. Such devices and methods are encompassed in the scope of the present invention as long as including the gist of the present invention.

What is claimed is:

1. A method for manufacturing a display device, the method comprising:
forming a display portion and a peripheral portion including a terminal portion on a first surface of a substrate, the peripheral portion being away from the display portion;
bonding a protecting member and a second surface of the substrate with an adhesive member, the second surface facing the first surface;
making an adhesive strength of a first region of the adhesive member and an adhesive strength of a second region of the adhesive member different from each other; and
removing a portion of the protective member from the substrate, the portion facing the first region,
wherein
the first region of the adhesive member includes a portion facing an intermediate portion which is between the display portion and the peripheral portion, and
the second region of the adhesive member includes a portion adjacent to the first region and facing the display portion or the peripheral portion.

2. The method for manufacturing a display device according to claim 1, wherein the first region faces an entirety of the intermediate portion, a part of the display portion that is adjacent to the intermediate portion, and a part of the peripheral portion that is adjacent to the intermediate portion.

3. The method for manufacturing a display device according to claim 1, wherein making the adhesive strengths different from each other includes irradiating at least one of the first region and the second region of the adhesive member with light.

4. The method for manufacturing a display device according to claim 1, wherein making the adhesive strengths different from each other includes heating at least one of the first region and the second region of the adhesive member.

5. The method for manufacturing a display device according to claim 1, wherein
the protective member includes a third region to be removed by the removing a portion of the protective member, and also includes a fourth region adjacent to the third region, and
the method further comprises forming a cut-out portion in the protective member before the removing a portion of the protective member, the cut-out portion being between the third region and the fourth region.

6. The method for manufacturing a display device according to claim 5, wherein
the protective member has a third surface facing the substrate and a fourth surface opposite to the third surface, and
the cut-out portion extends from the fourth surface toward the third surface and does not to reach the third surface.

7. The method for manufacturing a display device according to claim 5, wherein the cut-out portion is located over the protective member and the adhesive member.

8. The method for manufacturing a display device according to claim 1, wherein
the intermediate portion is folded, and
the display portion overlaps the peripheral portion as seen in a plan view.

9. The method for manufacturing a display device according to claim 1, wherein the display portion includes organic EL elements.

10. A method for manufacturing a display device, the method comprising:
forming a display portion and a peripheral portion including a terminal portion on a first surface of a substrate, the peripheral portion being away from the display portion;
bonding a protecting member and a second surface of the substrate with a viscous member, the second surface facing the first surface;
making a viscous strength of a first region of the viscous member and a viscous strength of a second region of the viscous member different from each other; and
removing a portion of the protective member from the substrate, the portion facing the first region,
wherein
the first region of the viscous member includes a portion facing an intermediate portion which is between the display portion and the peripheral portion, and
the second region of the viscous member includes a portion adjacent to the first region and facing the display portion or the peripheral portion.

11. The method for manufacturing a display device according to claim 10, wherein the making the viscous strengths different from each other includes irradiating at least one of the first region and the second region of the viscous member with light.

12. The method for manufacturing a display device according to claim 10, wherein the making the viscous strengths different from each other includes heating at least one of the first region and the second region of the viscous member.

13. A display device, comprising:
a substrate having a first surface and a second surface facing the first surface;
a display portion located on the first surface, the display portion including pixels;
a peripheral portion located on the first surface and away from the display portion, the peripheral portion including a terminal portion;
a first protective member located on the second surface, the first protective member facing the display portion;
a second protective member located on the second surface, the second protective member facing the peripheral portion;
a first adhesive member located between the second surface and the first protective member;
a second adhesive member located between the second surface and the second protective member; and
a third adhesive member located at a first portion adjacent to a first end of the first adhesive member and at a second portion adjacent to a second end of the second adhesive member, the first end facing the second adhesive member, the second end facing the first adhesive member, the second portion being separated from the first portion,
wherein the third adhesive member has an adhesive strength weaker than an adhesive strength of the first adhesive member and an adhesive strength of the second adhesive member.

14. The display device according to claim 13, wherein the pixels include organic EL elements.

15. The display device according to claim 13, further comprising an intermediate portion between the display portion and the peripheral portion, wherein
the intermediate portion is in a folded state, and
the display portion overlaps the peripheral portion as seen in a plan view.

16. The display device according to claim 15, wherein neither the first protective member nor the second protective member is provided on a portion of the second surface facing the intermediate portion.

17. The display device according to claim 13, wherein the third adhesive member includes a fourth adhesive member located between the second surface and the first protective member and a fifth adhesive member located between the second surface and the second protective member, the fifth adhesive member being separated from the fourth adhesive member.
